(19) United States
(12) Patent Application Publication
(10) Pub. No.: US 2025/0248185 A1
(43) Pub. Date: Jul. 31, 2025

(54) DISPLAY PANEL AND DISPLAY DEVICE

(71) Applicants: Hefei Visionox Technology Co., Ltd., Hefei (CN); Visionox Technology Inc., Suzhou (CN)

(72) Inventors: Zhiwei ZHOU, Hefei (CN); Jinfang ZHANG, Hefei (CN); Zuquan HU, Hefei (CN); Lu ZHANG, Hefei (CN); Yulong MA, Hefei (CN)

(73) Assignees: Hefei Visionox Technology Co., Ltd., Hefei (CN); Visionox Technology Inc., Suzhou (CN)

(21) Appl. No.: 18/731,740

(22) Filed: Jun. 3, 2024

(30) Foreign Application Priority Data
Jan. 29, 2024 (CN) 202410123725.3

(51) Int. Cl. H01L 33/62; H01L 25/075; H01L 25/16; H01L 27/12; H01L 33/38

(52) U.S. Cl. CPC H10H 20/857; H01L 25/0753; H01L 25/167; H10D 86/481; H10D 86/60; H10H 20/831

(57) ABSTRACT

A display panel and a display device. The display panel includes: a first conductive layer including a plurality of first signal lines, which extend along a first predetermined direction and are spaced apart from each other in a second predetermined direction; a second conductive layer stacked with the first conductive layer in a thickness direction of the display panel and including a plurality of second signal lines, which extend along the second predetermined direction and are spaced apart from each other in the first predetermined direction. Each of the first signal lines includes a plurality of first segments which are spaced apart from each other in the first predetermined direction, with hollow areas being formed between adjacent ones of the first segments, and the first segments are connected to the second signal lines.

### CROSS REFERENCE TO RELATED APPLICATIONS

The present application claims priority to Chinese patent application No. 202410123725.3, filed on Jan. 29, 2024 and entitled with “DISPLAY PANEL AND DISPLAY DEVICE”, which is incorporated herein by reference in its entirety.

### TECHNICAL FIELD

The present application relates to the field of display technology, in particular to a display panel and a display device.

### BACKGROUND

Flat display devices based on Organic Light Emitting Display (OLED) or Light Emitting Diode (LED) or the like have been widely used in various consumer electronic products such as mobile phones, televisions, laptops, and desktops, etc. due to their advantages of higher image quality, power saving, thinner device body, and wider range of application, and become the mainstream of display devices.

### SUMMARY

In a first aspect, the embodiments of the present application provides a display panel, including: a first conductive layer including a plurality of first signal lines, which extend along a first predetermined direction and are spaced apart from each other in a second predetermined direction, and each of the first signal lines includes a plurality of first segments which are spaced apart from each other in the first predetermined direction, with hollow areas being formed between every adjacent ones of the first segments; and a second conductive layer stacked with the first conductive layer in a thickness direction of the display panel and including a plurality of second signal lines, which extend along the second predetermined direction and are spaced apart from each other in the first predetermined direction, and the second signal lines are connected to the first segments.

According to any of implementations of the first aspect of present application, the display panel further includes: a base plate, in which the first conductive layer and the second conductive layer are disposed, an isolation structure disposed on a side of the base plate and including a plurality of transparent openings and at least two isolation openings; and a light-emitting layer including a plurality of light-emitting units which are disposed within the isolation openings, wherein a plurality of projections of at least a part of the plurality of transparent openings in the thickness direction are spaced apart from a plurality of projections of the first segments in the thickness direction.

In a second aspect, the embodiments of the present application provides a display device, including the display panel according to any of implementations as described above.

### BRIEF DESCRIPTION OF THE DRAWINGS

In order to provide a clearer explanation of the technical solutions of the embodiments of the present application, a brief introduction will be made to the accompanying drawings required in the embodiments of the present application. It is evident that the accompanying drawings described below are only some embodiments of the present application. For those skilled in the art, other accompanying drawings can be obtained based on these drawings without inventive efforts.

FIG. 1 is a schematic diagram of a local structure of a first conductive layer and a second conductive layer according to an embodiment of the present application;

FIG. 2 is a schematic diagram of a local structure of a first conductive layer and a second conductive layer according to another embodiment of the present application;

FIG. 3 is a schematic structural diagram of a display panel according to an embodiment of the present application;

FIG. 4 is a partial sectional view of a display panel according to an embodiment of the present application;

FIG. 5 is a schematic diagram of a local structure of an isolation structure according to an embodiment of the present application;

FIG. 6 is a schematic diagram of a local structure of a first conductive layer, a second conductive layer and a third conductive layer according to an embodiment of the present application;

FIG. 7 is a schematic diagram of a local structure of a third conductive layer and third signal lines according to an embodiment of the present application; and

FIG. 8 is a schematic diagram of a local structure of a first conductive layer, a second conductive layer and a third conductive layer according to another embodiment of the present application.

### EXPLANATIONS OF REFERENCE SIGNS

10. Display panel;

100. Base plate; 110. Substrate; 120. First insulation layer; 130. Second insulation layer; 140. Third insulation layer; 150. Fourth insulation layer; 160. Fifth insulation layer; 170. Transistor; 171. Gate; 172. Source & drain; 180. Storage capacitor; 181. First electrode plate; 182. Second electrode plate; 190. Third signal line; 191. First sub signal line; 192. Second sub signal line;

200. First conductive layer; 210. First signal line; 210a, Hollow area; 211, First segment;

300. Second conductive layer; 310. Second signal line;

400. Third conductive layer; 410. Compensation signal line;

500. First electrode layer; 510. First electrode;

600, Pixel definition part;

700. Isolation structure; 700a, Isolation opening; 700b, Transparent opening; 710. First isolation part; 720, Second isolation part;

800, Second electrode layer; 810. Second electrode;

900. Light-emitting layer; 910. Light-emitting unit;

A1. First display area;

A2. Second display area;

A3, Non-display area;

X—First predetermined direction;

Y—Second predetermined direction;

Z—Thickness direction.

### DETAILED DESCRIPTION

The present embodiment provides a display panel and a display device, and various embodiments of the display panel and display device will be described below in conjunction with the accompanying drawings.

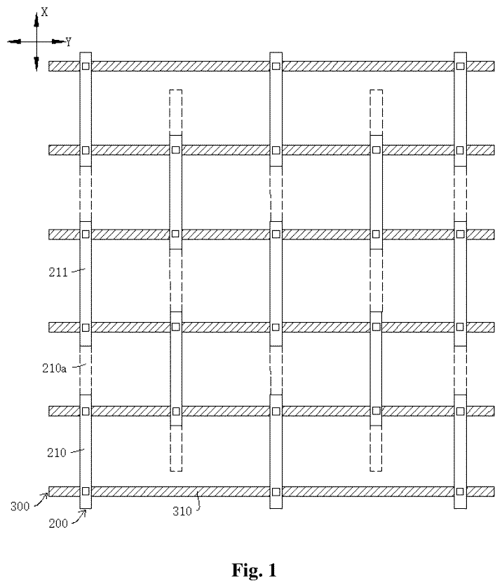

FIG. 1 is a schematic diagram of a local structure of a first conductive layer 200 and a second conductive layer 300 according to an embodiment of the present application. An X direction in the FIG. 1 is a first predetermined direction, a Y direction in the FIG. 1 is a second predetermined direction, and a Z direction in the FIG. 1 is a thickness direction of display panel 10. An area within a dashed box in the FIG. 1 represents a hollow area 210a. An area within a box at an intersection of signal lines in the FIG. 1 represents an electrical connection area. For example, the area within the box at an intersection of signal lines in the FIG. 1 may represents a via connection area. When there is no box marked at an intersection of signal lines in the FIG. 1, it should be understood that the signal lines at that intersection are insulated from each other.

As shown in FIG. 1, embodiments of a first aspect of the present application provides a display panel 10. The display panel includes: a first conductive layer 200 including a plurality of first signal lines 210, which extend along a first predetermined direction X and are spaced apart from each other in a second predetermined direction Y, and each of the first signal lines 210 includes a plurality of first segments 211 which are spaced apart from each other in the first predetermined direction X, with hollow areas 210a being formed between every adjacent ones of the first segments 211; and a second conductive layer 300 stacked with the first conductive layer 200 in a thickness direction Z of the display panel 10 and including a plurality of second signal lines 310, which extend along the second predetermined direction Y and are spaced apart from each other in the first predetermined direction X, and the second signal lines 310 are connected to the first segments 211.

In the embodiment of the present application, the display panel 10 includes a first conductive layer 200 and a second conductive layer 300. The first conductive layer 200 includes a plurality of first signal lines 210, which extend along a first predetermined direction X and are spaced apart from each other in a second predetermined direction Y, each of the first signal lines 210 includes a plurality of first segment 211 which are spaced apart from each other in the first predetermined direction X, and the first segments 211 are connected to the second signal lines 310, such that both the first signal lines 210 and the second signal lines 310 can be used to transmit signals in the display panel. Hollow areas 210a are formed between every adjacent ones of the first segments 211. The hollow areas 210a are provided on each of the first signal lines 210 such that light can propagate through the hollow areas 210a, which effectively reduces obstruction of light by the first signal lines 210 and improves transmittance of the display panel 10.

In some embodiments, at least two of the second signal lines 310 may be electrically connected through the first segments 211. For example, at least two of the second signal lines 310 which are adjacent to each other in the first predetermined direction X may be electrically connected through the first segments 211.

In the embodiments, the second conductive layer 300 is stacked with the first conductive layer 200 in the thickness direction Z of the display panel 10, and the second conductive layer 300 includes a plurality of second signal lines 310, which extend along the second predetermined direction Y and are spaced apart from each other in the first predetermined direction X. By electrically connecting at least two of the second signal lines 310 which are adjacent to each other in the first predetermined direction X through the first segments 211, resistance during signal transmission can be effectively reduced. Moreover, electrical connection between the first signal lines 210 and the second signal lines 310 can further facilitate signal transmission in the display panel 10, and reduce difficulty of controlling signals in the display panel 10.

In some embodiments, at least two of the first segments 211 may be electrically connected through the second signal lines 310. For example, at least two of the first segments 211 which are adjacent to each other in the second predetermined direction Y may be electrically connected through the second signal lines 310 to better improve arrangement density of the signal lines and further reduce the resistance during signal transmission.

In some embodiments, every adjacent ones of the second signal lines 310 in the first predetermined direction X may be electrically connected through the first segments 211, such that the first signal lines 210 and the second signal lines 310 can be well interwoven to form a grid mesh. Although the first segments 211 of each of the first signal lines 210 are disconnected at the hollow areas 210a therebetween for light transmission, every adjacent first segments 211 of each of the first signal lines 210 in the first predetermined direction X can be electrically connected through the connected second signal lines 310 and another first segment 211 in another one of the first signal lines 210, thereby improving arrangement density of the signal lines, facilitating signal transmission in the display panel 10, and reduce difficulty of controlling signals in display panel 10.

In some embodiments, every adjacent ones of the second signal lines 310 in the first predetermined direction X may be electrically connected through at least two first segments 211, in order to further increase arrangement density of the signal lines and reduce the resistance during signal transmission.

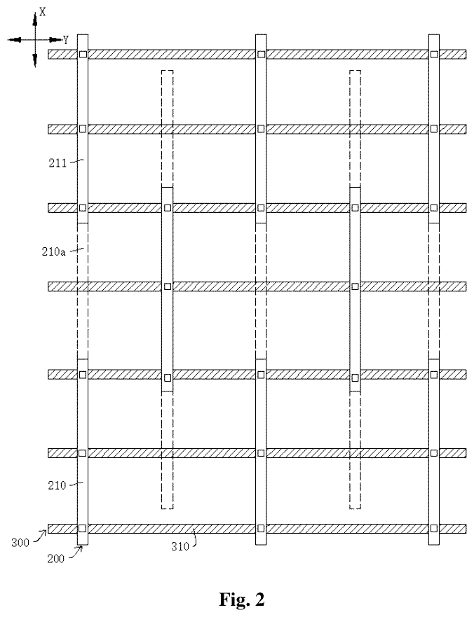

FIG. 2 is a schematic diagram of a local structure of a first conductive layer 200 and a second conductive layer 300 according to another embodiment of the present application.

In some embodiments of the present application, there are multiple ways to set a length of the first segment 211 in the first predetermined direction X. The length of the first segment 211 in the first predetermined direction X may be set according to specific resistance requirements of the first signal line 210. In some embodiments, as shown in FIG. 1, the first segment 211 may be connected only between two adjacent second signal lines 310 in the first predetermined direction X. The length of the first segment 211 in the first predetermined direction X may be greater than or equal to a distance between two adjacent second signal lines 310 in the first predetermined direction X. Alternatively, as shown in FIG. 2, the first segment 211 may be connected between two or more adjacent second signal lines 310 in the first predetermined direction X. The length of the first segment 211 in the first predetermined direction X may be greater than or equal to twice the distance between two adjacent second signal lines 310 in the first predetermined direction X.

In some embodiments of the present application, there are multiple ways to set a length of the hollow area 210a in the first predetermined direction X. The length of the hollow area 210a in the first predetermined direction X may be set according to light transmission requirements of the display panel 10. For example, as shown in FIG. 1, when there is no second signal line 310 between the two adjacent first segments 211 in the first predetermined direction X, the length of the hollow area 210a in the first predetermined direction X may be equal to or slightly less than the distance between the two adjacent second signal lines 310 in the first predetermined direction X. For example, as shown in FIG. 2, when a second signal line 310 is provided between two adjacent first segments 211 in the first predetermined direction X, the length of the hollow area 210a in the first predetermined direction X may be greater than the distance between two adjacent second signal lines 310 in the first predetermined direction X.

In some embodiments, there are multiple ways to set a shape of the second signal line 310. For example, the second signal line 310 may have hollow areas 210a similar to the first signal line 210 to reduce obstruction of light by the second signal line 310. Alternatively, as shown in FIGS. 1 and 2, the second signal line 310 may be formed by continuously extending in the second predetermined direction Y, that is, there may be no hollow area 210a on the second signal line 310, so that the second signal line 310 can have a better arrangement density to reduce a resistance of the second signal line 310. For ease of description, the following embodiments will be discussed by taking the second signal line 310 without a hollow area 210a as an example.

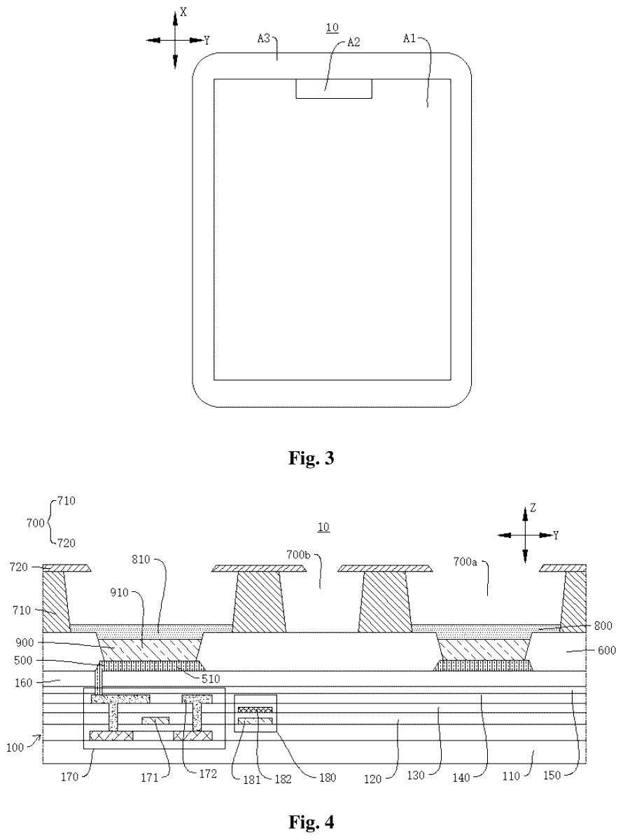

FIG. 3 is a schematic structural diagram of a display panel 10 according to an embodiment of the present application.

As shown in FIG. 3, in the embodiment of the present application, the display panel 10 may include a first display area A1 and a second display area A2, both of which are provided to achieve luminescent display.

In some embodiments, a transmittance of the second display area A2 may be greater than a transmittance of the first display area A1, such that when the display panel 10 is applied to a display device, photosensitive components in the display device for sensing light can be correspondingly set under the second display area A2, making the second display area A2 have less significant blocking effects on light, so that the photosensitive components can sense light well. The photosensitive component may include at least one of a distance sensor, a camera, an under-screen fingerprint recognition module, an infrared light emitting diode (IR LED) proximity sensor, and the like, or any component capable of sensing light, for example.

In some embodiments, the hollow areas 210a may be located in the second display area A2 to effectively reduce obstruction of the first signal lines 210 on light in the second display area A2, so that the second display area A2 can have better light transmittance. The hollow areas 210a may not be located in the first display area A1, that is, the first signal lines 210 in the first display area A1 may have a larger extension size, which reduces resistance in the first display area A1 and improves reliability of signal transmission.

In some embodiments, the first signal lines 210 and the second signal lines 310 located in the first display area A1 may have good continuity, that is, there may be no hollow area 210a on the first signal lines 210 and the second signal lines 310 in the first display area A1, so that the first signal lines 210 and the second signal lines 310 in the first display area A1 can be interworen to form a grid mesh with a higher density. In other words, the first signal lines 210 and the second signal lines 310 in the first display area A1 can have a better arrangement density, which effectively reduce the resistance in the first display area A1.

FIG. 4 is a partial sectional view of a display panel 10 according to an embodiment of the present application.

As shown in FIG. 4, in some embodiments, the display panel 10 may further includes a substrate 110 and a base plate 100 disposed on a side of the substrate 110. There are multiple ways to set the base plate 100. For example, the base plate 100 may include a plurality of transistors 170 disposed on a side of the substrate 110. In some embodiments, each of the transistors 170 includes a gate 171 and a source 172 and a drain 172 disposed on a side of the gate 171 away from substrate 110. Exemplarily, the base plate may further include a storage capacitor 180. In some embodiments, the storage capacitor 180 may include a first electrode plate 181 and a second electrode plate 182 disposed on a side of the first electrode plate 181 away from the base plate 110.

As an example, the base plate 100 may further include a first insulation layer 120, a second insulation layer 130, and a third insulation layer 140 disposed on a side of the substrate 110 facing toward the transistors 170 and sequentially stacked on the substrate 110. The gate 171 and the first electrode plate 181 may be disposed in a same layer, for example, the gate 171 and the first electrode plate 181 may be disposed on a side of the first insulation layer 120 facing toward the substrate 110. The second electrode plate 182 may be disposed between the first insulation layer 120 and the second insulation layer 130, and the source and the drain 172 may be disposed between the second insulation layer 130 and the third insulation layer 140.

In the embodiment of the present application, there are various types of signals that can be transmitted by the first signal lines 210 and the second signal lines 310. For example, the first signal lines 210 and the second signal lines 310 are provided to transmit reset signals or positive power supply voltage signals. For ease of description, the embodiments will be described by taking the first signal lines 210 and the second signal lines 310 being provided for transmitting reset signals as an example.

In some embodiments, the plurality of transistors 170 may include a reset transistor, at least one of the first signal line 210 and the second signal line 310 is connected to the reset transistor to transmit a reset signal to the reset transistor. For example, at least one of the first signal line 210 and the second signal line 310 may be connected to the source or the drain 172 of the reset transistor to transmit a reset signal to the reset transistor. In some embodiments, it may be that the second signal line 310 is connected to the reset transistor to transmit the reset signal to the reset transistor. The second signal lines 310 with good continuity in the second predetermined direction Y can be conveniently connected to corresponding reset transistors of respective sub pixels, and the second signal lines 310 respectively have a relatively smaller resistance.

In some embodiments, the first conductive layer 200 and the second conductive layer 300 may be disposed in the base plate 100. In some embodiments, the first signal lines 210 and the second signal lines 310 may be electrically connected with vias. There are various ways to set specific locations of the first conductive layer 200 and the second conductive layer 300. In some embodiments, the first conductive layer 200 may be disposed in a same layer as the source and drain 172, such that the first conductive layer 200 may be prepared in a same preparation process as the source and drain 172 of the transistor 170, in order to improve the preparation efficiency of the display panel 10.

In some embodiments, the second conductive layer 300 may be disposed between the first conductive layer 200 and the substrate 110. For example, the second conductive layer 300 may be disposed in a same layer as the gate 171, such that the second conductive layer 300 may be prepared in a same preparation process as the gate 171 of the transistor 170, in order to improve preparation efficiency of the display panel 10. As another example, the second conductive layer 300 may be disposed in a same layer as the second electrode plate 182, such that the second conductive layer 300 may be prepared in a same preparation process as the second electrode plate 182 of the storage capacitor 180, in order to improve the preparation efficiency of the display panel 10.

In some embodiments, the second conductive layer 300 may be disposed on a side of the first conductive layer 200 away from the substrate 110. For example, the base plate 100 may further include a fourth insulating layer 150 disposed on a side of the third insulating layer 140 away from the substrate 110. The second conductive layer 300 may be disposed between the third insulating layer 140 and the fourth insulating layer 150 to facilitate arrangement of the second signal lines 310.

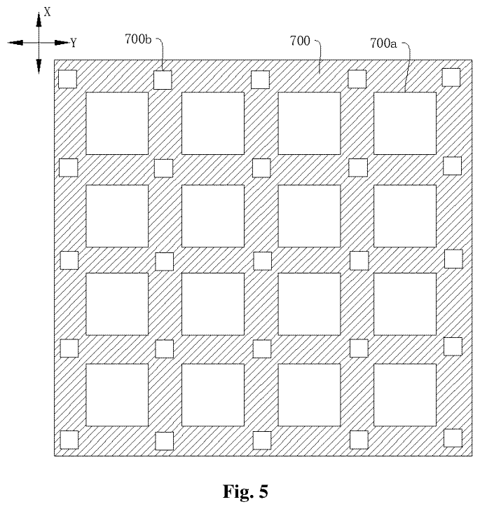

FIG. 5 is a schematic diagram of a local structure of an isolation structure 700 according to an embodiment of the present application.

As shown in FIGS. 4 and 5, in some embodiments, the display panel 10 may further include: an isolation structure 700 disposed on a side of the base plate 100 and including transparent opening 700b and at least two isolation openings 700a; a light-emitting layer 900 including a plurality of light-emitting units 910 which are disposed within the isolation openings 700a, wherein a plurality of projections of at least a part of the plurality of transparent openings 700b in the thickness direction Z are spaced apart from a plurality of projections of the first segments 211 in the thickness direction Z.

In some embodiments, the isolation structure 700 may have a shape of a grid mesh, and hollow parts of the grid mesh of the isolation structure 700 provide the isolation openings 700a and the transparent openings 700b. In some embodiments, at least a part of the plurality of transparent openings 700b may be located between adjacent ones of the isolation openings 700a.

In these embodiments, the light-emitting units 910 can be used to participate in the luminous display of the display panel 10. The light-emitting units 910 are disposed within the isolation openings 700a on the isolation structure 700, so that the isolation structure 700 can be used to divide sub pixels of the display panel 10. By providing the transparent openings 700b on the isolation structure 700 and setting that a plurality of projections of at least a part of the plurality of transparent openings 700b in the thickness direction Z are spaced apart from a plurality of projections of the first segments 211 in the thickness direction Z, that is, setting that the plurality of projections of at least apart of the plurality of transparent openings 700b in the thickness direction Z do not overlap with the plurality of projections of the first segments 211 in the thickness direction Z, light can be better propagated through the hollow areas 210a on the first signal line 210 and the transparent openings 700b, in order to reduce obstruction by the isolation structure 700 of light passing through the hollow areas 210a, thereby improving the transmittance of the display panel 10.

In some embodiments, a projection of the transparent opening 700b in the thickness direction Z may refer to an area surrounded by a projection of an inner wall of the transparent opening 700b which is formed by being surrounded by the isolation structure 700 in the thickness direction Z. In some embodiments, the plurality of projections of at least a part of the plurality of transparent openings 700b in the thickness direction Z being spaced apart from the plurality of projections of the first segments 211 in the thickness direction Z may refer to that the hollow areas 210a are located corresponding to the transparent openings 700b, which allows light to pass through the hollow areas 210a and the transparent openings 700b well to propagate.

In some embodiments, there may be a plurality of hollow areas 210a and a plurality of transparent openings 700b. In some embodiments, a number of hollow areas 210a may be smaller than a number of transparent openings 700b, that is, projections of a part of the transparent openings 700b in the thickness direction Z may not be overlapped with the projections of the first segments 211 in the thickness direction Z, and projections of the other part of the transparent openings 700b in the thickness direction Z may be at least partially overlapped with the projections of the first segments 211 in the thickness direction Z, such that the first segments 211 can have their good size in the first predetermined direction X, to facilitate electrical connection of each of the first segments 211 with at least two adjacent second segments in the first predetermined direction X Between signal lines 310. In some embodiments, the number of hollow areas 210a may be equal to the number of transparent openings 700b, so that projections of the transparent openings 700b in the thickness direction Z are all spaced apart from the projections of the first segments 211 in the thickness direction Z, which allow light to pass through the hollow areas 210a and the transparent openings 700b well to propagate.

In some embodiments, projections of the second signal lines 310 in the thickness direction Z does not overlap with the projections of the transparent openings 700b in the thickness direction Z, which means that the second signal lines 310 can be arranged bypass the transparent openings 700b, so that light will not be easily obstructed by the second signal lines 310 and can pass through the transparent openings 700b well.

In some embodiments, projections of the first signal lines 210 in the thickness direction Z does not overlap with projections of the isolation openings 700a in the thickness direction Z, so that the first signal lines 210 can be arranged between adjacent sub pixels to reduce impacts of the first signal lines 210 on arrangement of other devices in the base plate 100 below the sub pixels.

In some embodiments of the present application, the isolation structure 700 can be used to partition the material of the light-emitting layer 900 during preparation of the light-emitting layer 900 to achieve division of sub pixels. There are multiple ways to set the shape of the isolation structure 700. The isolation structure 700 can be any shape that can partition the material of the light-emitting layer 900 within adjacent isolation openings 700a.

As shown in FIG. 4, in some embodiments, the isolation structure 700 may include a first isolation part 710 and a second isolation part 720 disposed on a side of the first isolation part 710 away from the base plate 100. The second isolation part 720 may protrude from the first isolation part 710 toward the isolation opening 700a.

By protruding the second isolation part 720 from the first isolation part 710 towards the isolation opening 700a, the second isolation part 720 can block at least a part of material for preparing the light-emitting layer 900 of the display panel 10 during evaporation of the light-emitting layer 900, to partition the light-emitting layer 900 between adjacent sub pixels and facilitate formation of multiple spaced light-emitting units 910, which eliminates the need to set a high-precision mask during evaporation of the light-emitting layer 900 of the display panel 10. For example, it eliminates the need to set a high-precision metal mask (Fine Metal Mask, FMM) during evaporation of the light-emitting layer 900, thereby effectively reducing production and manufacturing costs of the display panel 10.

In some embodiments, in a direction away from the base plate 100, the display panel 10 may further includes a first electrode layer 500 and a second electrode layer 800. The first electrode layer 500 includes first electrodes 510 disposed on a side of the light-emitting units 910 facing toward the base plate 100, and the second electrode layer 800 includes second electrodes 810 disposed on a side of the light-emitting units 910 away from the base plate 100.

In some embodiments, each of the light-emitting units 910 may include a hole injection layer (HIL), a hole transport layer (HTL), a light-emitting structure, an electron injection layer (EIL), and an electron transport layer (ETL).

In these embodiments, the first electrode layer 500 and the second electrode layer 800 may serve as pixel electrode layers of the display panel 10, with one of the first electrode 510 and the second electrode 810 serving as an anode and the other as a cathode, to drive the light-emitting unit 910 to emit light. The embodiments of the present application will be described by taking the first electrode 510 being the anode of the display panel 10, and the second electrode 810 being the cathode of the display panel 10 as an example.

In some embodiments, the isolation structure 700 may include a conductive material. For example, the first isolation part 710 may include a conductive material, and the second electrodes 810 within adjacent ones of the isolation openings 700a are electrically connected through the isolation structure 700. That is, the second electrodes 810 within adjacent isolation openings 700a can be connected to each other through the isolation structure 700 to form a surface electrode, which facilitates control of the second electrodes 810 in the display panel 10.

In some embodiments, the display panel 10 may further include a pixel definition part 600 disposed between the isolation structure 700 and the first electrodes 510, making it less likely to have a short circuit connection between the isolation structure 700 and the first electrodes 510, that is, making it less likely to have a short circuit connection between the first electrodes 510 and the second electrodes 810 through the isolation structure 700, and thus light-emitting display reliability of the display panel 10 can be effectively improved.

In some embodiments of the present application, there are various ways to set the relative position between the pixel definition part 600 and the isolation structure 700. For example, as shown in FIG. 4, the isolation structure 700 may be disposed on a side of the pixel definition part 600 away from the base plate 100, that is, the isolation structure 700 may be directly disposed on the pixel definition part 600. Alternatively, for example, the pixel definition part 600 may have accommodating slots, and at least a part of the isolation structure 700 may be located within the accommodating slots such that the isolation structure 700 is not too high compared with the base plate 100, thereby effectively reducing the thickness of the display panel 10.

In some embodiments, the plurality of transistors 170 may further include a driving transistor for transferring a driving current, which flows through the first electrodes 510 to drive the light-emitting units 910 to emit light.

In some embodiments of the present application, there may be a plurality of reset transistors connected to at least one of the first signal lines 210 and the second signal lines 310, and the reset transistors may be connected to some devices in the display panel 10 to transmit respective reset signals.

In some embodiments, a part of the reset transistors is provided to be connected to a control end of the driving transistor to transmit a reset signal to the control end of the driving transistor, in order to reset the control end of the driving transistor. For example, a part of the reset transistors can be connected to the gate 171 of the driving transistor to transmit a reset signal to the gate 171 of the driving transistor.

In some embodiments, a part of the reset transistors is provided to be connected to an output of the driving transistor to transmit a reset signal to the output of the driving transistor, in order to reset the output of the driving transistor. For example, a part of the reset transistors can be connected to the source or drain 172 of the driving transistor to transmit a reset signal to the source or drain 172 of the driving transistor.

In some embodiments, a part of the reset transistors is provided to be connected to the first electrode 510 to transmit a reset signal to the first electrode 510 for resetting.

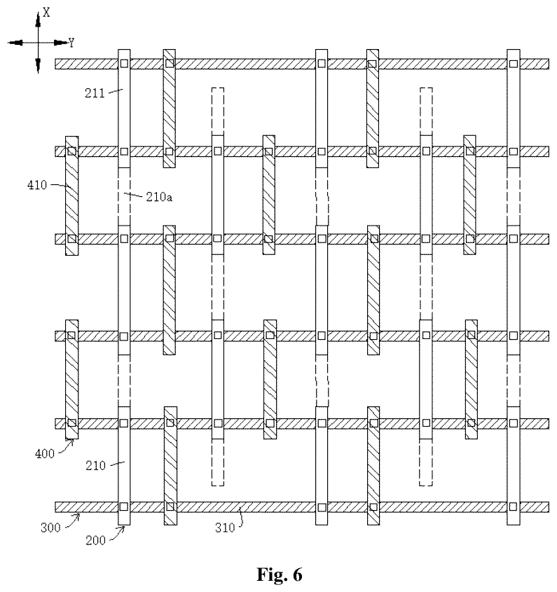

FIG. 6 is a schematic diagram of a local structure of a first conductive layer 200, a second conductive layer 300, and a third conductive layer 400 according to an embodiment of the present application.

As shown in FIG. 6, in some embodiments, the display panel 10 may further includes a third conductive layer 400, which includes compensation signal lines 410, a projection of the compensation signal line 410 in the thickness direction Z does not overlap with the projection of the hollow area 210a in the thickness direction Z. The compensation signal lines 410 are formed by extending along the first predetermined direction X, and connected to the second signal lines 310.

In some embodiments, at least two of the second signal lines 310 may be electrically connected through the compensation signal line 410. For example, at least two of the second signal lines 310 which are adjacent to each other in the first predetermined direction X may be electrically connected through the compensation signal line 410.

In this embodiment, due to the hollow areas 210a on the first signal lines 210, arrangement density and dimension of the first signal lines 210 may be influenced to a certain extent, which can easily increase the resistance during signal transmission between the first signal lines 210 and the second signal lines 310, thereby reducing working stability of the display panel 10. Therefore, by providing a third conductive layer 400 including compensation signal lines 410 and electrically connecting the compensation signal lines 410 with the second signal lines 310, the signals transmitted between the first signal lines 210 and the second signal lines 310 can also be transmitted through the compensation signal lines 410, which can effectively reduce the influence of the resistance which otherwise would be increased due to the hollow areas 210a on the first signal lines 210 and reduce the resistance during signal transmission between the first signal lines 210 and the second signal lines 310.

Moreover, by designing that a projection of the compensation signal line 410 in the thickness direction Z does not overlap with a projection of the hollow area 210a in the thickness direction Z, such setting of the compensation signal lines 410 is less likely to block the hollow areas 210a in the thickness direction Z, which allow light to easily pass through the hollow areas 210a, and thus the transmittance of the display panel 10 can be improved.

In some embodiments, the projection of the compensation signal line 410 in the thickness direction Z also does not overlap with a projection of the transparent opening 700b in the thickness direction Z, so such setting of the compensation signal lines 410 is less likely to block the transparent openings 700b in the thickness direction Z, which allow light to easily pass through the hollow areas 210a and the transparent openings 700b, and thus the transmittance of the display panel 10 can be improved.

In some embodiments of the present application, there are multiple ways to set the position of the third conductive layer 400, and in some embodiments, the third conductive layer 400 may be disposed in the base plate 100.

In some embodiments, the third conductive layer 400 may be disposed on a side of the first conductive layer 200 away from the substrate 110 to reduce the influence of the setting of the compensation signal lines 410 in the third conductive layer 400 on arrangement of other devices in the base plate 100, and to facilitate arrangement of the compensation signal lines 410 that are staggered from the hollow areas 210a and the transparent openings 700b. For example, the display panel 10 may further include FIAA (Fanout In AA) wirings, and the third conductive layer 400 may be disposed in a same layer and insulated from at least some of the FIAA wirings, such that the compensation signal lines 410 can be prepared in a same preparation process as the FIAA wirings to improve preparation efficiency of the display panel 10. Specifically, the display panel 10 may further include a fifth insulation layer 160 disposed on a side of the fourth insulation layer 150 away from the substrate 110, and the third conductive layer 400 may be disposed between the fifth insulation layer 160 and the fourth insulation layer 150. In some embodiments, the fifth insulation layer 160 may serve as a flattening layer for the display panel 10.

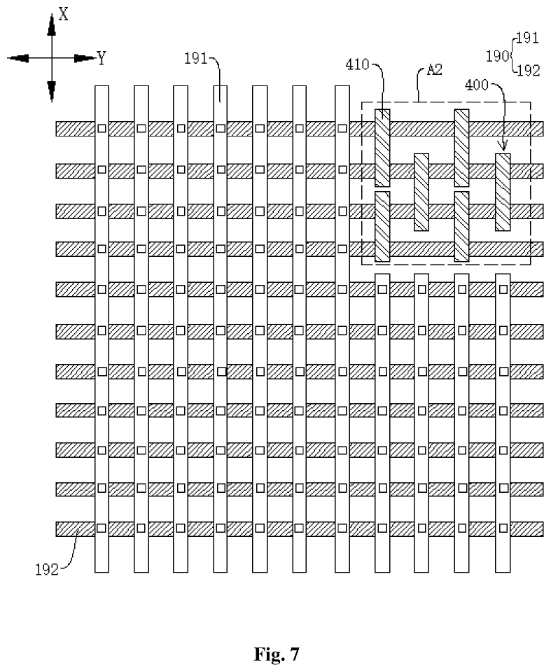

FIG. 7 is a schematic diagram of a local structure of a third conductive layer 400 and third signal lines 190 according to an embodiments of the present application.

In some embodiments, the display panel 10 may further include a plurality of third signal lines 190 insulated from the compensation signal lines 410, and at least a part of the plurality of third signal lines 190 is disposed in a same layer as the third conductive layer 400. The third signal line 190 may serve as the FIAA wirings for the display panel 10. For example, the third signal lines 190 may be at least partially disposed within the first display area A1 and/or the second display area A2.

In some embodiments, the third signal lines 190 are provided to transmit negative power supply voltage signals. For example, the third signal lines 190 may be electrically connected to the isolation structure 700 for transmitting the negative power supply voltage signals. As an example, the display panel 10 may further includes a non-display area A3, at least a part of the non-display area A3 can surround a peripheral side of the first display area A1 and/or the second display area A2, the third signal lines 190 may be partially disposed in the non-display area A3 and electrically connected to the isolation structure 700 in the non-display area A3.

In some embodiments, the third signal lines 190 includes first sub signal lines 191 and second sub signal lines 192 which are connected with each other. The first sub signal lines 191 are disposed in a same layer as the third conductive layer 400, while the second sub signal lines 192 are disposed between the third conductive layer 400 and the first conductive layer 200. For example, the first sub signal lines 191 may be disposed between the fifth insulation layer 160 and the fourth insulation layer 150, and the second sub signal lines 192 may be disposed between the fourth insulation layer 150 and the third insulation layer 140.

In some embodiments, the first sub signal lines 191 may be formed by extending along the first predetermined direction X and spaced apart from each other in the second predetermined direction Y, while the second sub signal lines 192 may be formed by extending along the second predetermined direction Y and spaced apart from each other in the first predetermined direction X.

In some embodiments, a number of compensation signal lines 410 is the same as a number of hollow areas 210a, such that the influence on the resistance during signal transmission generated at the respective hollow areas 210a on the first signal lines 210 can be improved by setting corresponding compensation signal lines 410. Moreover, only setting the same number of compensation signal lines 410 as the hollow areas 210a also ensures that the number of compensation signal lines 410 is not too large, such that more dense other devices can be disposed between the fourth insulation layer 150 and the fifth insulation layer 160, for example, more dense other signal lines can be disposed, to reduce the resistance of the display panel 10.

In some embodiments, the positions of the compensation signal lines 410 may be set according to the positions of the hollow areas 210a. In some embodiments, the compensation signal lines 410 may be disposed near the hollow areas 210a. For example, the compensation signal lines 410 seamy be disposed on either side of the hollow area 210a in the second predetermined direction Y such that the compensation signal lines 410 are disposed with respect to the positions of the respective hollow areas 210a. Thereby, the first signal lines 210, second signal lines 310, and compensation signal lines 410 can be arranged more evenly, so that the display panel 10 can have a more uniform resistance during signal transmission.

In some embodiments, as shown in FIG. 6, the second signal lines 310 located on both sides of the hollow area 210a in the first predetermined direction X may be connected with the compensation signal line 410. That is, the second signal lines 310 which are not electrically connected with the first segment 211 corresponding to the hollow area 210a may be electrically connected with the compensation signal line 410.

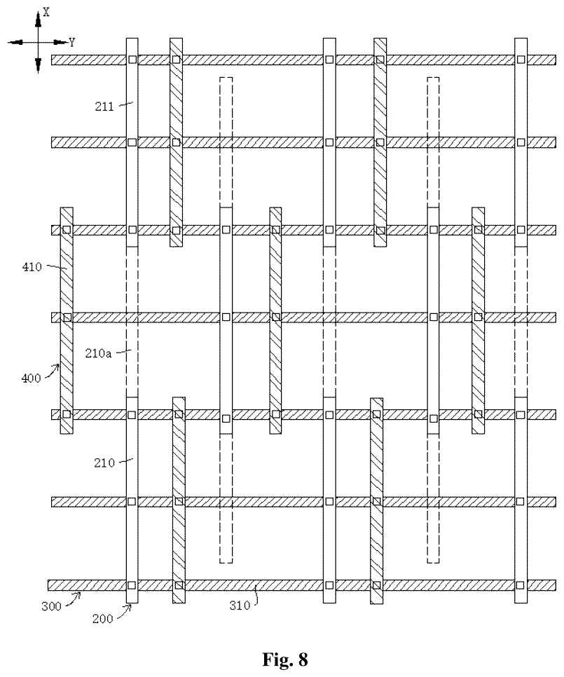

FIG. 8 is a schematic diagram of a local structure of a first conductive layer 200, a second conductive layer 300, and a third conductive layer 400 according to another embodiment of the present application.

In some embodiments, the compensation signal line 410 may be electrically connected to multiple adjacent second signal lines 310 in the first predetermined direction X. For example, as shown in FIG. 8, when an additional second signal line 310 is disposed between the second signal lines 310 located on both sides of the hollow area 210a in the first predetermined direction X, the compensation signal line 410 connecting the second signal lines 310 located on both sides of the hollow area 210a can also connect the additional second signal line 310, so that second signal lines 310 corresponding to the hollow area 210a that have not been connected with the first segment 211 are all electrically connected with compensation signal line 410.

In some embodiments, an extension length of the compensation signal line 410 may be set according to the size of the hollow area 210a. For example, the size of the compensation signal line 410 in the first predetermined direction X may be greater than or equal to the size of the hollow area 210a in the first predetermined direction X, that is, the size of the compensation signal line 410 in the first predetermined direction X can be greater than or equal to a distance between adjacent first segments 211 in the first predetermined direction X, in order to reduce the resistance increase effect caused by setting the hollow area 210a on the first signal line 210.

In some embodiments, the compensation signal line 410 may include a same material as the first signal line 210, for example, the compensation signal line 410 may include at least one material of aluminum and titanium. By setting the material of the compensation signal line 410 to be the same as the material of the first signal line 210, resistance characteristics of the material of the compensation signal line 410 are similar or identical to those of the material of the first signal line 210, which reduces the resistance increase effect caused by setting the hollow area 210a on the first signal line 210, and thereby the resistance of the display panel 10 will not have significant changes due to the setting of the hollow area 210a.

Please refer to FIGS. 1 to 8. the embodiment of the first aspect of the present application further provides a display panel 10, including: a base plate 100; an isolation structure 700 disposed on a side of base plate 100 and including a plurality of transparent openings 700b and at least two isolation openings 700a; a light-emitting layer 900 including a plurality of light-emitting units 910 which are disposed within the isolation openings 700a; and a first conductive layer 200 disposed in the base plate 100 and including a plurality of first signal lines 210, with hollow areas 210a being provided on each of the first signal lines 210, a plurality of projections of at least a part of the plurality of transparent openings 700b in the thickness direction Z are spaced apart from a plurality of projections of the first segments 211 in the thickness direction Z.

In the display panel 10 according to the embodiments of the present application, the light-emitting units 910 are provided to participate in the luminous display of the display panel 10. The light-emitting units 910 are disposed within the isolation openings 700a on the isolation structure 700, such that the isolation structure 700 can be used to divide sub pixels of the display panel 10. By providing the transparent openings 700b on the isolation structures 700 on the isolation structure 700 and the hollow areas 210a on the first signal lines 210, and designing that a plurality of projections of at least a part of the plurality of transparent openings 700b in the thickness direction Z are spaced apart from a plurality of projections of the first segments 211 in the thickness direction Z, light can propagate well bypassing through the transparent openings 700b of the isolation structure 700 and the hollow areas 210a of the first signal lines 210, which reduces obstruction of light by the isolation structure 700 and the first signal lines 210, and thus transmittance of the display panel 10 can be improved.

In some embodiments, the embodiment of the first aspect of the present application further provides a display panel 10 which may be the display panel 10 in any of the aforementioned embodiments. Therefore, the display panel 10 in the embodiment of the present application can also attain the same beneficial effects as the display panel 10 in any of the aforementioned embodiments, which will not be further repeated here. For example, the base plate 100 may be the base plate 100 in any of the aforementioned embodiments. For example, the light-emitting layer 900 may be the light-emitting layer 900 in any of the aforementioned embodiments, and the display panel 10 may further include the first electrode layer 500 and the second electrode layer 800 in any of the aforementioned embodiments. For example, the isolation structure 700 may be the isolation structure 700 in any of the aforementioned embodiments, and the isolation structure 700 may include the first isolation part 710 and the second isolation part 720 in any of the aforementioned embodiments, such that the isolation structure 700 is provided to partition the material of the light-emitting layer 900 when preparing the light-emitting 900 to achieve divisional of sub pixels. For example, the first signal lines 210 may be the first signal lines 210 in any of the aforementioned embodiments. The first signal lines 210 may formed by extending along the first predetermined direction X and spaced in the second predetermined direction Y. As an example, the first signal lines 210 may be provided to transmit reset signals or a positive power supply voltage signals. Each of the first signal lines 210 may include first segment 211 spaced apart from each other in the first predetermined direction X, with hollow area 210a being formed between adjacent ones of the first segments 211.

In some embodiments, the display panel 10 may further include the second conductive layer 300 in any of the aforementioned embodiments, the second conductive layer 300 may be disposed in the base plate 100 and stacked with the first conductive layer 200 in the thickness direction Z. As an example, the second conductive layer 300 may include second signal lines 310 which are electrically connected with the first segments 211. The first signal lines 210 are formed by extending along the first predetermined direction X and spaced apart from each other in the second predetermined direction Y, while the second signal lines 310 are formed by extending along the second predetermined direction Y and spaced apart from each other in the first predetermined direction X.

In some embodiments, at least two of the second signal lines 310 may be electrically connected through the first segment 211. For example, at least two of the second signal lines 310 which are adjacent to each other in the first predetermined direction X may be electrically connected through the first segment 211, to effectively reduce the resistance during signal transmission. Electrical connection between the first signal lines 210 and the second signal lines 310 can further facilitate signal transmission in the display panel 10, and reduce difficulty of controlling signals in the display panel 10.

In some embodiments, the display panel 10 may further include a third conductive layer 400 in any of the aforementioned embodiments, the third conductive layer 400 may be disposed in the base plate 100, and the third conductive layer 400 may include the compensation signal lines 410 in any of the aforementioned embodiments. For example, the projection of the compensation signal line 410 in the thickness direction Z does not overlap with the projection of the hollow area 210a in the thickness direction Z, and the compensation signal lines 410 are formed by extending along the first predetermined direction X, and are connected to the second signal lines 310.

In some embodiments, at least two of the second signal lines 310 are electrically connected through the compensation signal line 410, for example, at least two of the second signal lines 310 which are adjacent to each other in the first predetermined direction X may be electrically connected through the compensation signal line 410.

In some embodiments, in the display panel 10 according to the embodiment of the present application, arranged positions, extension sizes, electrical connection relationships, and materials of the first signal lines 210, the second signal lines 310, and the compensation signal lines 410 may be set according to the display panel 10 in any of the aforementioned embodiments.

Embodiments of a second aspect of the present application provide a display device, including the display panel 10 in any of the above embodiments. Due to the fact that the display device provided in the embodiments of the second aspect of the present application includes the display panel 10 in any one of the embodiments of the first aspect mentioned above, the display device provided in the embodiments of the second aspect of the present application has the same beneficial effects as the display panel 10 in any of the embodiments of the first aspect mentioned above, and will not be repeated here.

The display device in the embodiment of the present application may include, but is not limited, a device with a display function such as a mobile phone, a Personal Digital Assistant (PDA), a tablets, an e-books, a televisions, an access control, a smart landline phone, a console, etc.

In some embodiments, the display panel 10 may include a first display area A1 and a second display area A2, and a transmittance of the first display area A1 may be lower than that of the second display area A2. The display device may include a plurality of photosensitive components for sensing light in the second display area A2. In some embodiments, the photosensitive components may be disposed corresponding to the hollow areas 210a in the second display area A2. For example, a plurality of orthographic projections of at least a part of the plurality of photosensitive components on the base plate 100 are within a plurality of orthographic projections of the hollow areas 210a on the base plate 100, such that light can well be sensed by the photosensitive components through the hollow areas 210a.

In some embodiments, there are multiple ways to set the types of photosensitive components. For example, the photosensitive components may include at least one of a distance sensor, a camera, an under-screen fingerprint recognition module, an infrared light emitting diode (IR LED) proximity sensor, and the like, or any component capable of sensing light, for example.

According to the embodiments described in the present application, these embodiments do not fully describe all the details, nor do they limit the present application to the specific embodiments. Obviously, based on the above description, many modifications and changes can be made. The present application selects and specifically describes these embodiments in order to better explain the principles and practical applications of the present application, so that those skilled in the art can make good use of the present application and modifications based on the present application. The present application is only limited by the claims and all equivalents within their scope.

What is claimed is:

1. A display panel, comprising:
a first conductive layer comprising a plurality of first signal lines, which extend along a first predetermined direction and are spaced apart from each other in a second predetermined direction, each of the first signal lines comprises a plurality of first segments which are spaced apart from each other in the first predetermined direction, with hollow areas being formed between every adjacent ones of the first segments; and
a second conductive layer stacked with the first conductive layer in a thickness direction of the display panel and comprising a plurality of second signal lines, which extend along the second predetermined direction and are spaced apart from each other in the first predetermined direction, the second signal lines are connected to the first segments.

2. The display panel according to claim 1, wherein at least two of the second signal lines are electrically connected through the first segment; and
at least two of the second signal lines which are adjacent to each other in the first predetermined direction are electrically connected through the first segment.

3. The display panel according to claim 1, wherein at least two of the first segments are electrically connected through the second signal line; and
at least two of the first segments which are adjacent to each other in the second predetermined direction are electrically connected through the second signal line.

4. The display panel according to claim 1, wherein the display panel further comprises a third conductive layer which comprises a plurality of compensation signal lines, a projection of the compensation signal line in the thickness direction does not overlap with a projection of the hollow area in the thickness direction, and the compensation signal lines are formed by extending along the first predetermined direction, and connected to the second signal lines;
at least two of the second signal lines are electrically connected through the compensation signal line;
the display panel comprises a substrate and a base plate disposed on a side of the substrate, the first conductive layer, the second conductive layer and the third conductive layer are disposed in the base plate, and the third conductive layer is disposed on a side of the first conductive layer away from the substrate.

5. The display panel according to claim 4, wherein a number of the compensation signal lines is the same as a number of the hollow areas.

6. The display panel according to claim 4, wherein the second signal lines which are disposed on both sides of the hollow area in the first predetermined direction are electrically connected with the compensation signal line.

7. The display panel according to claim 4, wherein the compensation signal line comprises a same material as the first signal line; and
the compensation signal line comprises at least one material of aluminum and titanium.

8. The display panel according to claim 4, wherein the display panel further comprises a plurality of third signal lines which are insulated from the compensation signal lines, and at least part of the plurality of third signal lines is disposed in a same layer as the third conductive layer;
the third signal lines are provided to transmit negative power supply voltage signals;
the third signal line comprises first sub signal lines and second sub signal lines which are connected with each other, the first sub signal lines are disposed in a same layer as the third conductive layer, and the second sub signal lines are disposed between the third conductive layer and the first conductive layer; and
the first sub signal lines are formed by extending along the first predetermined direction and spaced apart from each other in the second predetermined direction, while the second sub signal lines are formed by extending along the second predetermined direction and spaced apart from each other in the first predetermined direction.

9. The display panel according to claim 1, further comprising:
a base plate, in which the first conductive layer and the second conductive layer are disposed;
an isolation structure disposed on a side of the base plate and comprising a plurality of transparent openings and at least two isolation openings; and
a light-emitting layer comprising a plurality of light-emitting units which are disposed within the isolation openings,
wherein a plurality of projections of at least part of the plurality of transparent openings in the thickness direction are spaced apart from a plurality of projections of the first segments in the thickness direction.

10. The display panel according to claim 9, wherein a projection of the second signal line in the thickness direction does not overlap with a projection of the transparent opening in the thickness direction.

11. The display panel according to claim 9, wherein a projection of the first signal line in the thickness direction does not overlap with a projection of the isolation opening in the thickness direction.

12. The display panel according to claim 9, wherein the isolation structure comprises a first isolation part and a second isolation part disposed on a side of the first isolation part away from the base plate, the second isolation part protrudes from the first isolation part towards the isolation opening;
in a direction away from the base plate, the display panel further comprises a first electrode layer and a second electrode layer, the first electrode layer comprises first electrodes disposed on a side of the light-emitting units facing toward the base plate, and the second electrode layer comprises second electrodes disposed on a side of the light-emitting units away from the base plate;
the isolation structure comprises a conductive material, and the second electrodes within adjacent ones of the isolation openings are electrically connected through the isolation structure; and
the display panel further comprises a pixel definition part disposed between the isolation structure and the first electrodes.

13. The display panel according to claim 1, wherein the first signal lines and the second signal lines are provided to transmit reset signals or positive power supply voltage signals.

14. The display panel according to claim 13, wherein the first signal lines and the second signal lines are provided to transmit reset signals, and the display panel further comprises a base plate, the base plate comprises a substrate and a plurality of transistors disposed on a side of the base plate, the plurality of transistors comprises a reset transistor, and at least one of the first signal line and the second signal line is connected to the reset transistor.

15. The display panel according to claim 14, wherein each of the transistors comprises a gate and a source and a drain disposed on a side of the gate away from the base plate, the source and the drain are disposed in a same layer as the first conductive layer; and
the gate is disposed in a same layer as the second conductive layer, or the base plate further comprises a storage capacitor, the storage capacitor comprises a first electrode plate disposed in a same layer as the gate and a second electrode plate disposed on a side of the first electrode plate away from the base plate, and the second electrode plate is disposed in a same layer as the second conductive layer.

16. The display panel according to claim 1, wherein the display panel comprises a first display area and a second display area, and the hollow areas are located in the second display area; and
a transmittance of the second display area is greater than a transmittance of the first display area.

17. A display panel, comprising:
a base plate;
an isolation structure disposed on a side of the base plate and comprising a plurality of transparent openings and at least two isolation openings;
a light-emitting layer comprising a plurality of light-emitting units which are disposed within the isolation openings; and
a first conductive layer disposed in the base plate and comprising a plurality of first signal lines, with hollow areas being provided on each of the first signal lines, a plurality of projections of at least part of the transparent openings in a thickness direction are spaced apart from a plurality of projections of the first signal lines in a thickness direction.

18. The display panel according to claim 17, wherein the first signal lines are formed by extending along a first predetermined direction and spaced apart from each other in a second predetermined direction;
the display panel further comprises a second conductive layer disposed in the base plate and stacked with the first conductive layer in the thickness direction, the second conductive layer comprises a plurality of second signal lines which are electrically connected to the first signal lines, and the second signal lines are formed by extending along the second predetermined direction and spaced apart from each other in the first predetermined direction;
each of the first signal lines comprises a plurality of first segments which are spaced apart from each other in the first predetermined direction, with hollow areas being formed between every adjacent ones of the first segments, and the first segments are connected to the second signal lines;
at least two of the second signal lines are electrically connected through the first segment;
at least two of the second signal lines which are adjacent to each other in the first predetermined direction are electrically connected through the first segment;
the first segments of at least two of the first signal lines are electrically connected through the second signal line;
a projection of the second signal line in the thickness direction does not overlap with a projection of the transparent opening in the thickness direction;
a projection of the first signal line in the thickness direction does not overlap with a projection of the isolation opening in the thickness direction;
the display panel further comprises a third conductive layer comprising a plurality of compensation signal lines, a projection of the compensation signal line in the thickness direction does not overlap with a projection of the hollow area in the thickness direction, and the compensation signal lines are formed by extending along the first predetermined direction and connected to the second signal lines;
at least two of the second signal lines are electrically connected through the compensation signal line;
the base plate comprises a substrate, and the third conductive layer is located on a side of the first conductive layer away from the substrate;
a number of the compensation signal lines is the same as a number of the hollow areas;
the second signal lines which are disposed on both sides of the hollow area in the first predetermined direction are connected with the compensation signal line;
the compensation signal line comprises a same material as the first signal line; and
the compensation signal line comprises at least one material of aluminum and titanium.

19. The display panel according to claim 16, wherein the first signal lines and the second signal lines are provided to transmit reset signals or positive power supply voltage signals;
the first signal lines and the second signal lines are provided to transmit reset signals, the base plate comprises a substrate and a plurality of transistors disposed on a side of the base plate, the plurality of transistors comprise a reset transistor, and at least one of the first signal line or the second signal line is connected to the reset transistor;
each of the transistors comprises a gate and a source and a drain which are disposed on a side of the gate away from the base plate, and the source and the drain are disposed in a same layer as the first conductive layer; and
the gate is disposed in a same layer as the second conductive layer, or the base plate further comprises a storage capacitor, the storage capacitor comprises a first electrode plate disposed in a same layer as the gate and a second electrode plate disposed on a side of the first electrode plate away from the base plate, and the second electrode plate is disposed in a same layer as the second conductive layer.

20. A display device, comprising the display panel according to claim 1.
